(19) United States
(12) Patent Application Publication
(10) Pub. No.: US 2015/0047897 A1
(43) Pub. Date: Feb. 19, 2015

(54) METHOD AND APPARATUS FOR USE IN PROVIDING WIRE STRAIN RELIEF WITH ENVIRONMENTALLY PROTECTED IRRIGATION DEVICES

(71) Applicant: Rain Bird Corporation, Azusa, CA (US)

(72) Inventors: Daniel B. Zimet, Carlsbad, CA (US); Bashir Z. Eslam, San Marcos, CA (US); Roger S. Neitzel, Escondido, CA (US); Douglas S. Busch, Tucson, AZ (US)

(21) Appl. No.: 14/457,715

(22) Filed: Aug. 12, 2014

Related U.S. Application Data
(60) Provisional application No. 61/865,517, filed on Aug. 13, 2013.

(51) Int. Cl. H02G 3/08; A01G 9/02; H05K 3/30

(52) U.S. Cl. CPC H02G 3/088; H05K 3/30; A01G 9/02
USPC 174/521; 29/841

(57) ABSTRACT

Some embodiments comprise apparatuses providing an electrical conductor guide for use with an irrigation device comprising: a housing having a volume and containing an electronic component and one or more electrical conductors coupled thereto; a support structure having one or more apertures each configured to allow at least one of the one or more electrical conductors to extend therethrough; and a potting material at least partially filling and sealing the volume from an external environment, wherein the one or more electrical conductors extend out of the potting material and the housing; wherein the support structure is cooperated with the one or more electrical conductors and is configured to inhibit movement of the one or more electrical conductors relative to the potting material due to external forces applied to the one or more electrical conductors to reduce the forces applied to the potting material or to electronic component.

This application claims the benefit of U.S. Provisional Application No. 61/865,517, filed Aug. 13, 2013, by Daniel B. Zimet, et al. and is entitled METHOD AND APPARATUS FOR USE IN PROVIDING WIRE STRAIN RELIEF WITH ENVIRONMENTALLY PROTECTED IRRIGATION DEVICES, which is incorporated in its entirety herein by reference.

### BACKGROUND

1. Field of the Invention

The present invention relates generally to irrigation, and more specifically to irrigation devices.

2. Discussion of the Related Art

It is important to maintain levels of moisture within plant life. Accordingly, irrigation is utilized throughout the world in attempts to maintain water levels within plant life. Typically, many different devices are cooperatively utilized in order to effectively irrigate. Because of the distribution of water, many irrigation devices are continuously and/or repeatedly exposed to water.

### SUMMARY OF THE INVENTION

Some embodiments comprise apparatuses providing an electrical conductor guide for use with an irrigation device comprising: a housing having a volume and containing an electronic component and one or more electrical conductors coupled thereto; a support structure having one or more apertures each configured to allow at least one of the one or more electrical conductors to extend therethrough; and a potting material at least partially filling the volume and sealing the volume from an external environment, wherein the one or more electrical conductors extend out of the potting material and the housing; wherein the support structure is cooperated with the one or more electrical conductors and is configured to inhibit movement of the one or more electrical conductors relative to the potting material due to external forces applied to the one or more electrical conductors to reduce the forces applied to the potting material or to the electronic component.

Some embodiments provide methods of protecting electrical components of an irrigation device, the methods comprising: positioning a support structure relative to a device, the support structure comprising one or more apertures formed in the support structure and the device comprising one or more electrical components within a volume defined by a housing of the device with one or more electrical conductors coupled with the one or more electrical components and extending out of the housing, wherein the positioning the support structure comprises positioning the support structure such that the one or more electrical conductors extend through the one or more apertures and out of the housing of the device; and incorporating a potting material into the volume to encapsulate at least part of the electrical components and at least a portion of the one or more electrical conductors within the volume; wherein the one or more apertures are configured to support the corresponding one or more electrical conductors to inhibit movement of the one or more electrical conductors at least proximate an interface between the potting material and the one or more electrical conductor.

### BRIEF DESCRIPTION OF THE DRAWINGS

The above and other aspects, features and advantages of several embodiments of the present invention will be more apparent from the following more particular description thereof, presented in conjunction with the following drawings.

FIG. 1 depicts a simplified perspective view of an exemplary electronic device, in accordance with some embodiments, intended to be utilized in an environment that exposes the device to moisture.

FIG. 2A shows a perspective view of an exemplary support structure, in accordance with some embodiments.

FIG. 2B shows a perspective view of an exemplary support structure in accordance with some embodiments.

FIG. 3 shows a simplified, partial view of an exemplary device or apparatus, in accordance with some embodiments, with a support structure that provides a wire guide and cooperates with the device.

FIG. 4A shows an exterior or top side perspective view of an exemplary support structure, in accordance with some embodiments.

FIG. 4B shows an interior or bottom side perspective view of the exemplary support structure of FIG. 4A, in accordance with some embodiments.

FIG. 5 shows a perspective view of a wire guide support structure of FIGS. 4A-4B cooperated with an exemplary device, in accordance with some embodiments.

FIG. 6 shows a partial, cross-sectional view of the support structure cooperated with the device of FIG. 5, in accordance with some embodiments.

FIG. 7 depicts a simplified, partial perspective view of an exemplary electronic device with one or more wires extending from the device, in accordance with some embodiments.

FIG. 8 shows a support structure cooperated with the exemplary device of FIG. 5, further showing potting material filling a volume of the device.

FIG. 9A shows a partial cross-sectional view of a support structure with an exemplary sleeve that cooperates with and/or is fixed to a jacket of a wires, in accordance with some embodiments.

FIG. 9B shows a support structure of FIG. 9A with the exemplary sleeve positioned within a wire aperture of the support structure 410, in accordance with some embodiments.

FIGS. 9C-9E show representations of exemplary sleeves in accordance with some embodiments.

FIGS. 9F-9G show cross-sectional views of exemplary sleeves, in accordance with some embodiments.

FIG. 10A depicts a perspective view of an exemplary device comprising a housing and a support structure cooperated with the housing, in accordance with some embodiments.

FIG. 10B depicts a perspective view of the exemplary support structure of FIG. 10A showing an exterior or top surface of the support structure, in accordance with some embodiments.

FIG. 10C depicts a perspective view of the exemplary support structure of FIG. 10A showing an interior or bottom surface of the support structure, in accordance with some embodiments.

FIG. 11 shows a cross-sectional, perspective view of the support structure of FIG. 10A, in accordance with some embodiments.

FIG. 12 shows a cross-sectional, perspective view of the support structure of FIG. 10A cooperated with a housing, in accordance with some embodiments.

FIG. 13 shows a simplified, plan view of an exemplary support structure, in accordance with some embodiments.

FIG. 14 shows a simplified, plan view of an exemplary support structure, in accordance with some embodiments.

FIG. 15 shows a simplified, partial, cross-sectional view of a support structure fixed with a housing of a device, in accordance with some embodiments.

FIG. 16 shows a simplified, partial, cross-sectional view of a support structure fixed with a housing of a device, in accordance with some embodiments.

FIG. 17 shows a simplified perspective view of an exemplary support structure in accordance with some embodiments.

FIGS. 18A-18B depict simplified perspective views of an exemplary sleeve in accordance with some embodiments.

FIG. 19 shows a simplified flow diagram of an exemplary process of protecting electrical components of a device, in accordance with some embodiments.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention.

### DETAILED DESCRIPTION

The following description is not to be taken in a limiting sense, but is made merely for the purpose of describing the general principles of exemplary embodiments. The scope of the invention should be determined with reference to the claims.

Reference throughout this specification to “one embodiment,” “an embodiment,” “some embodiments,” “some implementations” or similar language means that a particular feature, structure, or characteristic described in connection with the embodiment is included in at least one embodiment of the present invention. Thus, appearances of the phrases “in one embodiment,” “in an embodiment,” “in some embodiments,” and similar language throughout this specification may, but do not necessarily, all refer to the same embodiment.

Furthermore, the described devices, components, features, structures, or characteristics of the invention may be combined in any suitable manner in one or more embodiments. In the following description, numerous specific details are presented to provide a thorough understanding of embodiments of the invention. One skilled in the relevant art will recognize, however, that the invention can be practiced without one or more of the specific details, or with other methods, components, materials, and so forth. In other instances, well-known structures, materials, or operations are not shown or described in detail to avoid obscuring aspects of the invention.

Some devices containing electronics are designed to operate outdoors in environments that can be adverse to the electronics, and/or are designed to withstand rough handling and/or extreme conditions. In some of these devices, some or all of the electronics are encased or encapsulated in a material, typically a water resistant or water proof material, to provide protection for the electronics against an external environment and/or environmental conditions. The encapsulation is sometimes referred to as potting and the one or more materials used in encapsulating is sometimes referred to as the potting material or compound. For example, encapsulating electronic circuit boards and/or other electronic components of devices, which are to be exposed to moisture and/or submerged in water, with potting material having relatively low porosity can provide protection against water ingress to the circuit board and/or electronics for long periods.

It is often technically challenging when wires, cables or other such electrical conductors, which extend out of the potting material and connect to the one or more electronic component (e.g., circuit board containing additional electronic components, decoders, detectors, amplifiers, transformers, transceivers, or other such components or combinations of such components) sealed within the potting material, have to make electric connections to devices outside the potting material. One such problem is that the wires, typically being flexible, can twist, bend, and/or forces can be applied to the wiring. The twisting, bending and/or forces can open a gap between the wire and the potting material. Such a gap or opening can allow water to migrate to the circuit board and/or other electronics and cause damage to the circuit board and/or other electronics. In addition, such twisting, bending and/or forces applied to the wires (e.g., pulling force on the wires) can cause the wire insulation to slip out of the potting material and completely break connection to the circuit board, which would cause the device to fail.

For example, some irrigation valve actuators, sensors, two-wire communication device, relays, pump actuators and/or controllers, and/or other such device are constructed with a circuit board assembly that is held in a housing and has one or more communication wires coupled with and extending away from the circuit board. The circuit board is further encapsulated in a potting material (e.g., urethane, epoxy, or other such materials that are typically non-conductive) with the wires exiting the potting material and exposed to allow the wires to be coupled with one or more other devices (e.g., valve, pump, sensor, light, etc.) and/or one or more communication links. For example, the wires can connect to a communication path and the housing (e.g., molded plastic, PVC, etc.) is connected to a water flow control valve controlled by the irrigation valve actuator. Some potting material is at least marginally, elastically deformable and/or flexible so that forces applied to the wires can allow the wires, and in some instances the potting material, to move at an interface between the wire and the potting material and/or within the potting material. Such forces and/or movement can break an adhesive bond between the outer wire insulation or jacket and the potting material, and/or can allow water to enter the housing assembly at the interface between the potting material and the wires. This water could then potentially contact the circuit board assembly which can cause the circuit board to be damaged and/or fail.

Some electronic devices have used hard epoxy material as the potting material to prevent movement of the wires. In some implementations, however, the hard epoxy can damage electronic components, solder joints and/or other such electrical contacts of the device, for example, due to thermal expansion and contraction.

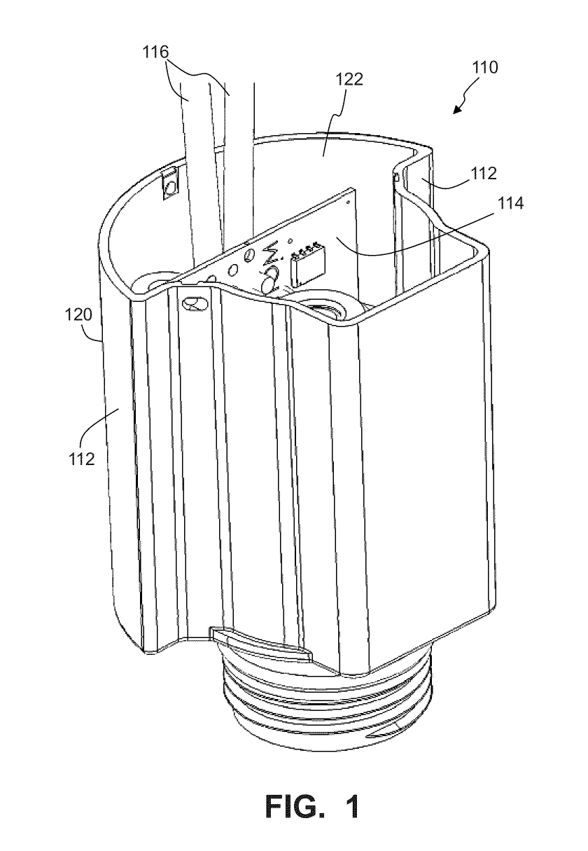

FIG. 1 depicts a simplified perspective view of an exemplary electronic device 110, in accordance with some embodiments, intended to be utilized in an environment that exposes the device 110 to moisture. For example, the device 110 can be an actuator (e.g., to actuate a valve, pump, lighting, etc.), a sensor, a relay, controller or other such device. The device 110 includes a housing 112, one or more electronic components and one or more wires 116, cables or other such electrical conductors. The one or more electronic components and/or electronics, in some embodiments, include one or more circuit boards 114, conductive wires, decoders, detectors, amplifiers, receivers, transmitters, transceivers, transformers, gates, actuators, and/or other such electronic components. The housing includes one or more walls 120 that define one or more volumes 122 within the housing. The circuit board 114 is positioned within the volume 122 of the housing 112. Typically, no electronic components and/or conductors of the circuit board 114 are outside the housing 112. The one or more wires 116 are electrically coupled with the circuit board 114 (or other electronics) and extending out of the housing 112.

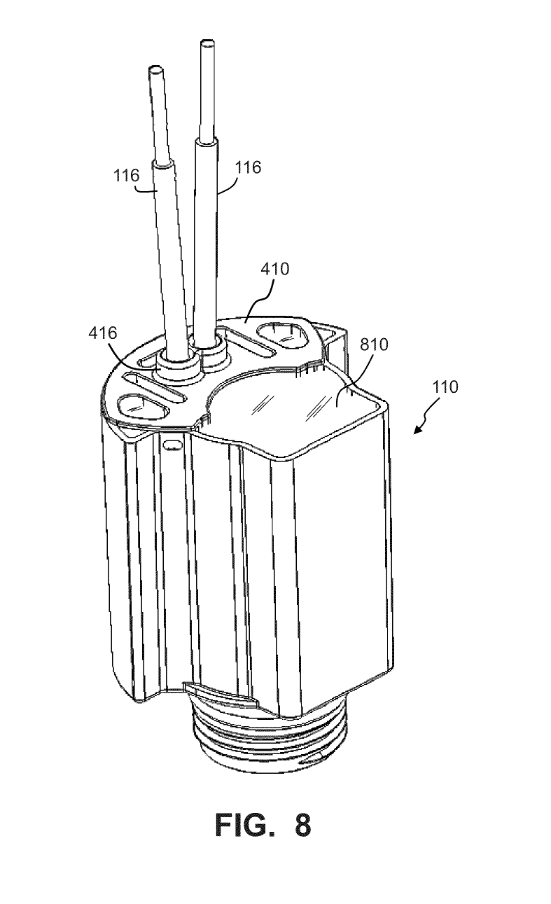

It is common for such a device 110 to be utilized in environments where the device is exposed to water and/or completely submerged in water or in soil that may become saturated with moisture. Accordingly, in some embodiments, a potting material (see FIG. 8) is added into the volume 122 in which the circuit board 114 is positioned. Further, in some embodiments, the volume 122 in which the circuit board is positioned is filled to at least a level that encapsulates at least critical portions of the circuit board and typically all of the circuit board. In some implementations, the volume 122 is substantially or completely filled with the potting material. The potting material is typically a relatively low porous material that is water resistant and/or water proof.

With the circuit board 114 encapsulated, portions of the one or more wire 116 are also encased in the potting material and extend out of the potting material. In applying the potting material to the volume 122 the potting materially typically bonds with the wires 116 sealing with the portions of the one or more wires 116 within the potting material. As described above, when the wires are bent, twisted and/or force is applied to the wires, the forces can cause a separation between the potting material and the wires producing a gap between the potting material and the jacket of the wire. The gap can allow water to get into the device and potentially damage the circuit board 114 and/or other electronics. Additionally, forces applied to the wires (e.g., by pulling or pushing the wires) can transfer through the potting material and compromise the connection point to the circuit board.

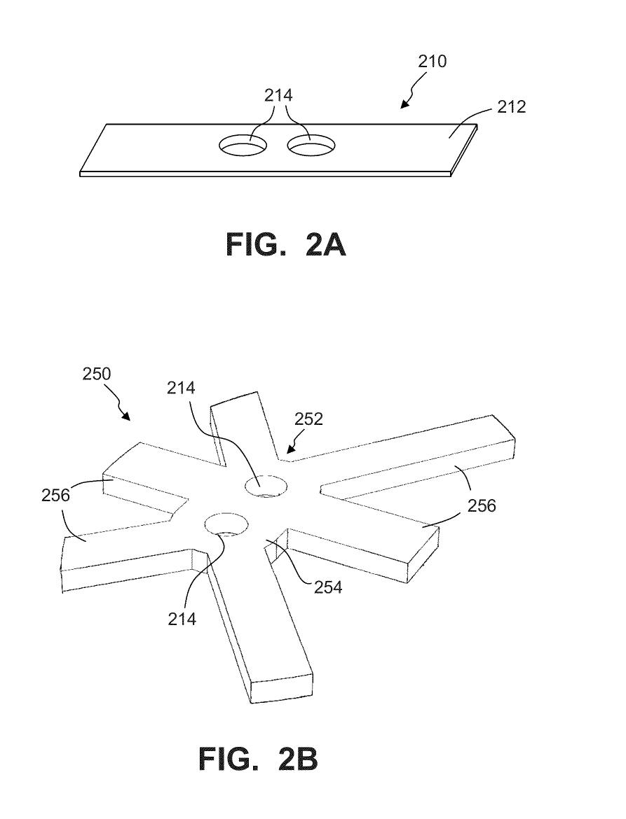

FIG. 2A shows a perspective view of an exemplary wire guide and/or wire support structure 210, in accordance with some embodiments. Generally, in some embodiments, the support structure functions at least in part to relieve strain on one or more wires extending into the potting material and/or connecting to the circuit board due to external forces applied on the wires. The support structure 210 includes a body 212 and one or more conductor or wire openings or apertures 214. The support structure 210 is configured to cooperate with a device 110 that includes electronics and that is at least partially encapsulated with potting material or other such material with one or more wires extending out of the potting material. For example, in some implementations, the support structure 210 cooperates with the housing 112 of the device 110. The support structure can be constructed from substantially any relevant material capable of withstanding forces expected to be applied to the wires 116 and/or device 110. For example, the support structure 210 is formed of plastic, polyurethanes, thermoplastic polyurethanes, polyvinyl chloride (PVC), acrylonitrile butadiene styrene (ABS), polyethylene, polypropylene, metal, ceramics or other such materials or combination of such materials.

FIG. 2B shows a perspective view of an exemplary support structure 250 in accordance with some embodiments. The support structure includes a body 252 and one or more wire apertures 214. The body includes a main body portion 254 and one or more branches 256 or extensions extending from the main body portion 254. In some embodiments, one or more of the branches 256 extend out to interface with and/or contact portions of a housing or casing of a device 110.

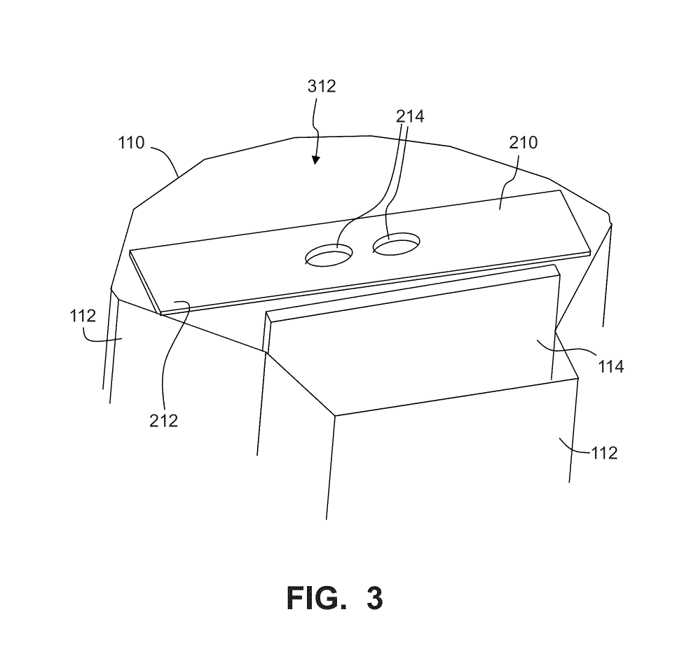

FIG. 3 shows a simplified, partial view of an exemplary device or apparatus 110, in accordance with some embodiments, with a support structure 210 that provides a wire guide and cooperates with the device 110. Wires 116 are not depicted in FIG. 3 for simplicity; however, those skilled in the art will appreciate that wires may pass through one or more of the wire apertures 214. Referring to FIGS. 1-3, the wire apertures 214 are formed in the body 212 of the support structure 210 and are configured to allow one or more wires to be passed through the wire apertures. In some embodiments, the wire apertures 214 maintain positioning of the wires relative to one or more other wires, the circuit board 114 and/or the housing 112. For example, the apertures control and fix the entry/exit location of the wires into/from the potting material. In some embodiments, the wire apertures 214 can be positioned within the support structure 210 to provide at least relatively consistent and in some instances uniform spacing of the wires and their immersion in potting material. Further, in some embodiments, the wire apertures 214 are configured to mechanically cooperate with the one or more wires to transfer at least some of the external forces applied to the wires to the support structure 210. For example, the jacket of a wire 116 can be in contact with one or more locations of a perimeter of a wire aperture 214. As such, when force is applied to the wire, at least some of that force may be applied to at least one of the one or more contact points between the wire aperture 214 and the jacket of the wire 116.

In some embodiments, the support structure 210 cooperates with the housing 112 of the device 110. Additionally or alternatively, the support structure 210 can mechanically cooperate and/or is bonded with the potting material (not shown in FIG. 3) that is incorporated into a volume 312 of the device 110. In some embodiments, when the support structure 210 is cooperated with the housing 112 and/or the potting material, some of the force applied to a wire extending through a wire aperture 214 may be transferred from the wire, through the support structure 210 and to the housing 112 and/or the potting material. The transfer of force reduces the force on the wire, at least at the junction between the potting material and the jacket of the wire, which reduces the likelihood that a gap will develop between the potting material and the wire.

The support structure 210 can be substantially any shape, configuration and/or material that can receive at least some of the forces applied to the wire 116. In FIG. 2A, the support structure 210 is shown generally as a plate structure having generally a rectangular shape. Other shapes may be employed. For example, some embodiments may utilize a support structure having generally an “X” shape, a triangular shape, a square shape, a main body portion 254 with one or more branches 246, or other such shapes. In some embodiments, the shape of the support structure 210 is at least partially dependent on the housing 112 and/or shape of the device 110 with which the support structure is intended to cooperate. Additionally, in some embodiments, the support structure 210 further provides at least some protection of the potting material from exposure to environmental elements. For example, often the devices 110 are utilized in outdoor environments, with exposure to sunlight and/or changing temperatures. The potting material may experience some deterioration due to the exposure to sunlight and/or the changing weather. In some embodiments, the support structure 210 covers some or all of the potting material and/or limits exposure at least to sunlight for some or all of the potting material. Further, in some instances, bugs and/or animals may eat or gnaw on the potting material. Accordingly, in some embodiments, the support structure 210 provides at least some protection to the potting material, at least proximate the interface where the wires exit the potting material, from animals and/or insects. Again, the support structure may be configured, in some embodiments, to cover most if not all of the potting material.

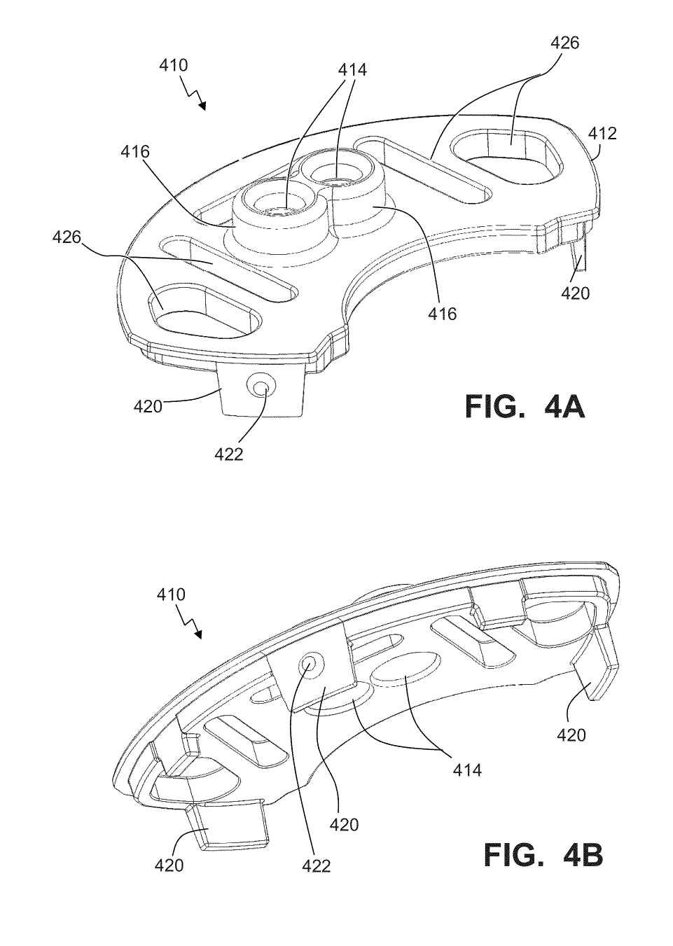

FIG. 4A shows an exterior or top side perspective view of an exemplary support structure 410, in accordance with some embodiments. FIG. 4B shows an interior or bottom side perspective view of the exemplary support structure 410 of FIG. 4A, in accordance with some embodiments. The support structure 410 includes a body 412 and one or more wire apertures 414. In some embodiments, the wire apertures 414 are part of a tube 416, channel or other such protrusion, elevation, recess or the like. Again, the shape, size and/or configuration of the support structure 410 can be dependent upon the device with which the support structure is to cooperate.

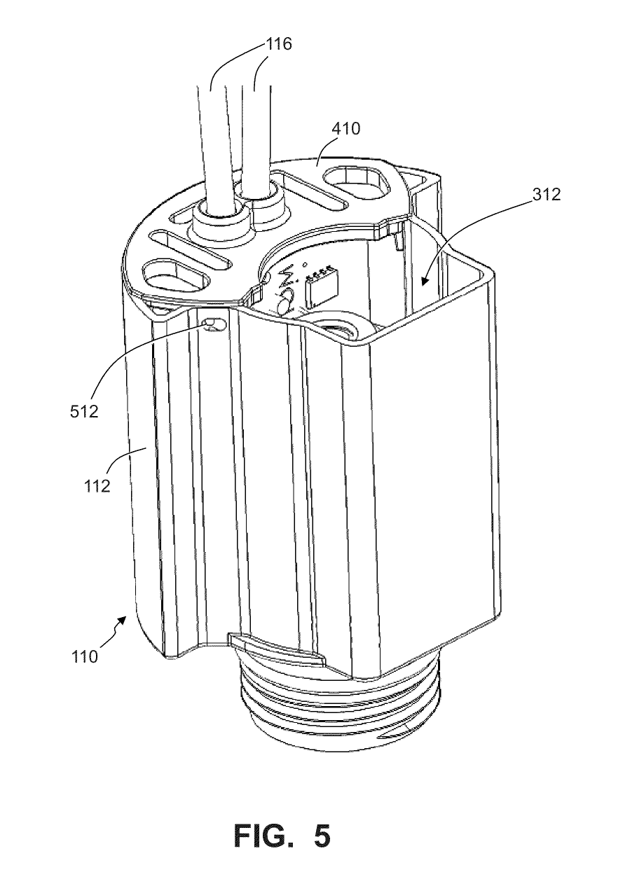

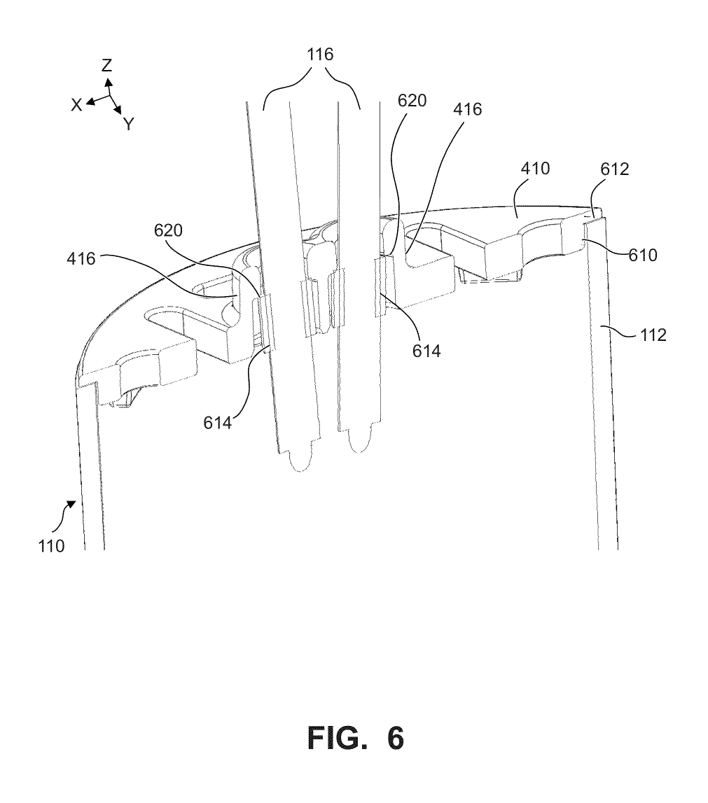

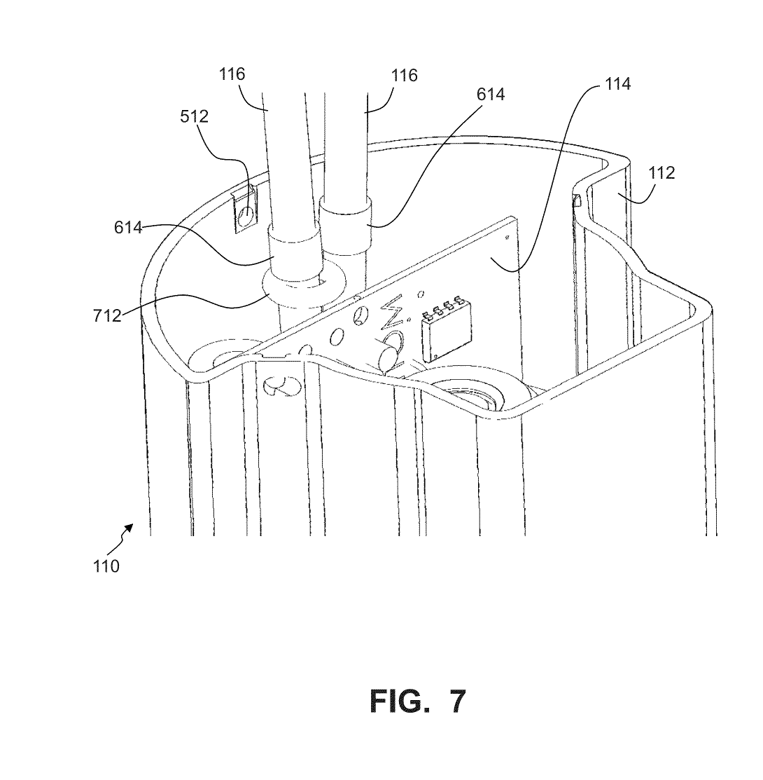

FIG. 5 shows a perspective view of a wire guide support structure 410 of FIGS. 4A-4B cooperated with an exemplary device 110, similar to that of FIG. 1, in accordance with some embodiments. FIG. 6 shows a partial, cross-sectional view of the support structure 410 cooperated with the device 110 of FIG. 5, in accordance with some embodiments. FIG. 7 depicts a simplified, partial perspective view of an exemplary electronic device 110 with the one or more wires 116, cables or other such electrical conductors and/or electrical conduits (e.g., insulated electrical conduits) extending from the device 110 and prior to a support structure 410 being cooperated with the device and wires 116, in accordance with some embodiments. FIG. 8 shows the support structure 410 cooperated with the exemplary device 110 of FIG. 5, further showing the potting material 810 filling the volume 312. It is noted that the support structure 410 is shown as a separate part that can be cooperated with the device 110; however, in some embodiments, the support structure can be configured as an integral part of the device 110 (e.g., formed from a molded material and extending from the walls of the device.

Similarly, the structure is shown as a single piece; however, in some embodiments, the support structure 410 may comprise multiple pieces that secure with the housing 112, and in some instances, may be connected or secured with one or more of the pieces.

Referring to FIGS. 4A-8, in this exemplary configuration, the support structure 410 has a shape similar to the shape of the housing 112 of the device 110 with which the support structure is intended to cooperate. In some embodiments, the support structure 410 cooperates with the housing 112 of the device 110 (e.g., at least a portion of the support structure physically contacts and/or engages a portion of the housing, is in contact with or engages another structure that is physically in contact with and/or engages the housing, etc.) and provides in part a wire guide or wire placement of the wires 116. In cooperating with the housing, the support structure 410 may include, in some embodiments, one or more shoulders 610 and/or corresponding shelves or lips 612 that contact and/or rest upon the housing 112. In some embodiments, the one or more shoulders 610 and lips 612 can be formed about at least a portion of the perimeter of the support structure 410 to cooperate with the housing 112. In other embodiments, the housing 112 may be formed with a ledge and/or shoulder upon which and/or into which the support structure 410 is positioned.

Further, in some embodiments, the shoulder 610 can be configured to compress and/or friction fit with at least one or more locations of the housing 112. The lip 612 is shown in FIG. 6 as having a reduced thickness; however, in other embodiments the thickness is maintained and/or increased at the lip. Further, the lip may be formed with a bend or the like. Additionally or alternatively, some embodiments use an adhesive or otherwise bond the support structure 410 with the housing 112. In some embodiments, one or more sections of the support structure 410 may extend over, beyond, and/or down along an exterior of the housing 112 of the device (e.g., the support structure may even include threading or other structure) to aid in securing and/or positioning the support structure 410 relative to the housing 112, circuit board 114 and/or wires 116.

The support structure 410, in some embodiments, additionally or alternatively includes one or more positioning extensions or protrusions 420 that can aid in positioning the support structure 410. For example, the positioning protrusions 420 may be configured to contact and/or extend down a portion of an inner wall of the housing 112. In some embodiments, the positioning protrusions 420 may further cooperate with the housing 112 to help position the support structure 410 and/or maintain a position of the support structure. Further, the one or more of the positioning protrusions 420 may additionally include a tab, bead, post, ledge or the like that can cooperate with a corresponding structure of the housing, such as through a snap fit, compression fit, friction fit or the like. For example, in some implementations the one or more positioning protrusions 420 include a hemispherical snap feature 422 (e.g., a bead, bump, etc. extending from a surface of the positioning protrusion 420) that mates with a corresponding hole 512, depression or the like in the housing 112 of the device 110. For example, the support structure may include three positioning protrusions 420 spaced about the body 412, each of the positioning protrusions including a hemispherical snap feature 422 that mate with one of three corresponding indentations or holes 512 in housing 112. In some instances, the hemispherical snap feature 422 at least partially seals a cylindrical hole 512, which can inhibit and/or prevent the potting material from leaking out of the hole 512 when the potting material is added in a liquid form into the volume 312. In other embodiments, the housing 112 includes the hemispherical snap feature or other such structure to cooperate with a hole, recess, ledge or the like in the positioning protrusion 420.

Further, the positioning protrusions 420 and snap features 422 are shown to extend into an interior of the housing 112; however, one or more or all of the positioning protrusions 420 (and snap features or other relevant feature) can alternatively or additionally extend along an outside of the housing. Again, other structures instead of the holes 512 can be formed in the housing 112 to cooperate with the positioning protrusions 420, such but not limited to a tab, ledge, recess, or other such structure. In the exemplary embodiment depicted in FIGS. 4A-4B, multiple positioning protrusions 420 are included extending from the body 412, and in this instance separated from a perimeter edge of the support structure 410 by the lip 612.

The one or more wire apertures 414 are each configured to allow one or more wires 116 to extend through the support structure 410 and in some instances guide and/or position wires. In some implementations, the sizes of the wire apertures 414 are configured to be substantially the same size or marginally larger than an expected size of the jacket of the wires 116. In other embodiments, the wire apertures 414 are constructed to contact the jacket of the wire at one or more locations about the jacket. For example, in some embodiments the wire apertures may include fingers or extensions that flex and/or grip as the wire is passed through the wire aperture to contact the jacket.

Additionally or alternatively, some embodiments further utilize one or more sleeves 614, crimps, clamps, clips, washers or other structures that cooperate with and/or are fixed to the jacket of at least one of the one or more wires 116. FIG. 7 shows a sleeve 614 cooperated with each wire 116 coupled with the circuit board 114 (or other electronics) and extending out of the housing 112 of the device 110. Some embodiments may additionally include a seal, such as an O-ring 712 or other such structure about one or more of the wires to further aid in inhibiting water penetration. Still referring to FIGS. 4A-8, the sleeves 614 are typically configured to have a size or diameter, when secured with the wire 116, that is larger than the wire aperture 414 or portion of the wire aperture through which the corresponding wire passes. The one or more wire apertures 414 in the support structure 410 are sized to allow the one or more wires 116 to pass through but not the sleeve 614. Further, in some embodiments, the sleeve 614 is positioned along the length of the wire at a point such that when fitted through the wire aperture the sleeve 614 contacts at least a portion of the support structure 410. Additionally or alternatively, in some embodiments the wire includes bends or uses a twisted, tortuous or serpentine path of the wire, and/or exits laterally farther away from its point of origin such that stresses applied to the wire are transferred to the support structure 410 rather than to the bond between the wire and the potting material. Further, some embodiments immersing a longer piece of the wire in the potting material, which can, in some instances, provide a stronger bond.

In the embodiment depicted in FIG. 6, the sleeve 614 extends up into the tube 416. Further, the sleeves 614 can be configured to contact a ledge 620, lip or other such structure of the wire aperture 414. In other embodiments, the wire apertures taper such that the sleeve 614 comes into contact with one or more points of the wall of the tube 416 as it tapers. Additionally or alternatively, in some implementations, the sleeve 614 is sized to contact the wall of the tube 416 and potentially create a seal at one or more locations along a length of the tube. For example, in some implementations, the sleeve 614 can be configured in the form of a grommet, O-ring or the like that is sized to contact the wall of the tube 416, the ledge 620, and/or a surface of the support structure 410 configured contact the potting material. In some embodiments, the sleeve 614 can be positioned on the wire 116 such that a force is applied by the wire, when inserted through or threaded through a wire aperture 414, to help maintain a position of the sleeve 614 against the wire aperture 414 at least until the potting material is added to the volume 312 and cured.

With the one or more wires 116 extending through the wire apertures 414, the support structure inhibits movement of the wires at least at an interface of the wire with the potting material. Forces externally applied on the wire (e.g., axial forces (along a longitudinal axis of the wire and generally perpendicular to the surface of the support structure, indicated in FIG. 6 as the Z axis) and/or lateral forces (generally perpendicular to an axis of the wire and generally parallel with the surface of the support structure, indicated in FIG. 6 as X and Y axes)) are transferred from the wire to the support structure 410 through the sleeve 614 and/or the wire aperture 414. Again, in some implementations, the support structure 410 is coupled with the housing 112 of the device 110, such as through a mechanical interference fit (e.g., shoulder 610 and/or the lip 612, the one or more positioning protrusions 420, or other such component or combinations of such components) and/or through contact and/or bonding with the potting material.

As described above, in many implementations, an adhesive bond is formed between the potting material and the support structure 410, and in some instances between the potting material and the housing 112, when the potting material is cured. Further, the support structure 410 can be shaped, in at least some embodiments, to contact the housing 112 at one or more locations. The support structure in part can restrict lateral movement of the one or more wires 116 with the wires and/or sleeve 614 contacting the support structure, and forces on the wires can be transferred to the support structure 410 and/or from the support structure to the housing 112 and/or potting material 810. Similarly, the support structure 410 typically further restricts movement of the one or more wires 116 when perpendicular tensile forces are exerted on the wires. As such, the support structure 410 at least in part provides strain relief to the device 110 limiting and/or preventing forces applied to the wires 116 from being transferred to the portion of the wire that is bonded with the potting material and/or the interface between the potting material and the jacket of the wire and/or forces transferred through the wire to the connection point between the circuit board and the wire. Instead, the forces are transferred to the support structure 410, housing and/or potting material, which provides a distribution of the forces over an area that is orders of magnitude larger than the small area of the bonding between the jacket of the wire and the potting material. This force redistribution and/or redirection inhibits and/or reduces deformation of the potting material at the interface between the wires and the potting material. Further, in those embodiments where the support structure cooperates with the housing 112, some of the forces can be transferred to the housing. Therefore, the adhesive bond between the wire jacket and the potting material is preserved; and thus, prevents or at least inhibits water from penetrating the assembly and causing damage to the circuit board 114.

Still referring to FIGS. 4A-8, the sleeve 614 is configured to secure with at least one wire or cable 116, typically with the jacket of the wire. As introduced above, the sleeve can be secured with the wire through substantially any method, such as but not limited to adhesive, shrink fit, clamping, crimping, friction, ribs, or other such methods or combinations of such methods. For example, in some embodiments, the sleeve is formed from a plastic, polyvinyl chloride, polyolefin or other such material that is heat shrunk and adhesive bonded with to the jacket of a wire 116 through the application of the heat. In other embodiments, the sleeve 614 may have angled teeth or other protrusion that allow the sleeve to slide along the wire in one direction but resist movement of the sleeve in the opposite direction. In still other embodiments, the sleeve 614 is a plastic, metal or other relevant material that is crimped onto the wire.

The sleeve 614 is configured to be secured with and/or grip the wire with enough force to withstand expected external forces on the wires. Typically, the sleeve when secured with the wire has a resulting width and/or diameter that is greater than the jacket of the wire. Further, the sleeve can be configured with a shape, size and/or outer width that interfaces with the support structure 410 and/or the ledge 620 of the wire aperture 414 and/or tube 416 to inhibit and/or prevent movement, at least in the axial direction, of the wire proximate the interface between the jacket of the wire and the potting material. In some embodiments, the sleeve is further configured and/or shaped to abut against some or all the interior of the tube 416 providing added stability and further inhibiting lateral movement of the wire at the interface between the jacket of the wire and the potting material.

In some embodiments, the sleeve 614 is positioned at a location along the length of the wire, in at least some embodiments, such that when the plate is position relative to the housing 112 and/or circuit board 114 there is a pre-load force caused by the wire pushing the sleeve against the support structure 410. This pre-loading can help maintain solid mechanical engagement between the sleeve 614, and thus the wire 116, with the support structure 410. Additionally, in some embodiments, the support structure 410 is secured with the housing 112 or other portion of the device 110 so that the support structure 410 is not displaced by the pre-loading force asserted by the wire, at least while the potting material is curing, and/or to maintain the pre-loading. Further, the preload force between the sleeve 614 and the support structure 410 inhibits and/or prevents a separation or gap between the sleeve and the support structure 410. A gap could potentially allow movement of the wire, which could allow the bond between the potting material and the wire and/or between the support structure and the sleeve to be broken by movement of the wires from external forces on the wire.

Again, in some embodiments, as depicted in FIGS. 4A-8, the support structure 410 includes one or more tubes 416, channels or other such structures associated with the one or more wire apertures 414. The tubes 416 extend from the body 412 of the support structure effectively extending the wire aperture and separating the wire aperture above the body. In other embodiments, the tubes 416 may extend below the body or a combination of below and above the body. In some embodiments, the tubes 416 further aid in limiting and/or preventing tangential forces on the wires 116 from being asserted at the interface where the wire exits the potting material and/or between the wire and the potting material. For example, the tubes can provide, in some instances, a resistance point for force applied to the wire 116 (e.g., help resist lateral bending movement of the wire).

Still further, the tubes 416 allow the corresponding one or more sleeves 614 to be positioned further from the circuit board than typically would otherwise be possible with those support structure configurations that do not include the tubes, particularly when the device 110 with which the support structure is being cooperated has relatively small and/or limited size constraints. Additionally or alternatively, allowing the sleeve to be positioned at least partially within the tube, and effectively positioning the sleeve further from the circuit board, can inhibit potential inadvertent contact between the sleeve and electrical components and/or electrically conductive traces of the circuit board, particularly when the sleeve is formed of a metallic structure. Furthermore, in at least some implementations, the tube 416 increases the distance between the movement of the wire (e.g., where the wire exits the wire aperture 414) and the interface between the wire and the potting material. The walls of the tube 416 extending along a portion of the length of the wire and/or sleeve 614, in some instances, can further inhibit the movement of the wire at least relative to the potting material.

As introduced above, the sleeve 614 can be made from substantially any relevant material that can be cooperated with the wire 116. For example, the sleeve 614 can be formed from one or more metals, plastics, thermoplastic polyurethanes, polyurethanes, ceramics or other such materials or combination of such materials. In some embodiments, the sleeve 614 has generally a hollow, cylindrical shape with an inner diameter that allows the wire to extend through the sleeve. The sleeve, however, can have substantially any other relevant shape, such as but not limited to generally spherical, cubic, trapezoidal, pyramid, cone, octagonal, octahedron, or other such shape that effectively interfaces with the support structure 410. In some embodiments, the sleeve can be formed with the wire (e.g., the wire can be formed with a portion having an enlarged or extended width, such as part of the jacket, providing an integrated sleeve) and/or secured with the wire through substantially any relevant method, such as but not limited to adhesive boding, thermal bonding, heat shrinking, crimping, clamping, friction force, biasing, threading, or other such methods or combination of such methods. In other embodiments, a component of the support structure 410 may maintain or help maintain the positioning of the sleeve relative to the wire and/or the support structure, such as a clamping, crimping, pinching, or other such component or combination of such components. Other structures and/or methods can be used in place of or in addition to the sleeve 614. For example, in some embodiments, a knot may be made in the wire where the knot abuts against the support structure 410. The knot can provide the pre-loading against the support structure 410 and/or prevent or inhibits movement of the wire at least axially, while the wire aperture 414 and/or tube 416 inhibit or prevents movement of the wire laterally. In other embodiments, the sleeve is incorporated into the support structure and/or the support structure includes one or more elements that can aid in maintaining the position of the wire and/or sleeve, such as one or more extended flanges or fingers, friction fitting, clamping or crimping element, or other such elements or combinations of such elements.

Still referring to FIGS. 4A-8, in some embodiments, the support structure 410 includes one or more additional apertures 426 and/or channels in at least the body 412. The one or more apertures 426, at least in part, allow gas (e.g., air) to escape from under the support structure 410 as the potting material is added into the volume 312 and is curing. As described above, in some embodiments, the potting material is incorporated into the volume 312 to at least partially fill the volume. Further, in some instances, the potting material is configured to contact the support structure and bond with the support structure. Accordingly, with the potting material filled to the support structure and/or encasing some or all of the support structure 410, the one or more additional apertures 426 allow bubbles in and/or formed in the potting material to escape from under the support structure. Furthermore, in some instances, the potting material may extend into the additional apertures 426 to further enhance the boding between the support structure 410 and the potting material.

Additionally, in some embodiments, one or more of the additional apertures 426 can be sized to allow the potting material to be incorporated into the volume 312 through the aperture 426. For example, one or more of the additional apertures 426 can be sized to receive an injection nozzle that injects the potting material into the volume 312 and/or allow the potting material to be poured or streamed into the volume through the additional aperture 426. The support structure 410 can include substantially any number, size and/or shape of additional apertures 426 while maintaining sufficient structural integrity and/or rigidity to support the wires 116 and reduce and/or prevent forces on the wires and/or movement of the wires proximate the interface between the potting material and the one or more wires 116. In some implementations, for example, the support structure 410 can comprise a lattice of support beams defining multiple holes.

The support structure 410, in some embodiments, may further include one or more additional fins, blades or protrusions (not shown) that are configured to extend into the housing 112 of the device to provide added boding surface area to bond with the potting material. In some embodiments, the one or more fins could include holes to allow potting material to extend into and/or through the holes to enhance bonding and/or further secure the position of the support structure. In some instances, the added stability can be beneficial in those implementations where the support structure 410 is not in contact with the housing 112 of the device. The one or more fins could extend from substantially any relevant portion of the support structure and do not have to be positioned at a periphery of the support structure.

Further, some implementations utilize a support structure 410 that opens and closes, for example to close around the one or more wires 116. In some instances, the support structure has one or more hinges, bend points, a clam shaped design, snap fit features, and/or other such configurations. Additionally, in some embodiments, the support structure 410 comprises two or more parts or pieces that cooperate together to form the support structure.

The embodiments of FIGS. 4A-4B show the tube 416 extending up from an upper or exterior surface of the body 412 of the support structure 410. In some embodiments, however, the tube 416 may additionally or alternatively be configured to extend into the housing 112 of the device 110, and in some instances terminate proximate to and/or in contact with the circuit board. The tube extending into the housing may further include additional appendages or flanges (e.g., a “X” configuration”) to increase surface area to bond with the potting material. With sufficient surface area, some embodiments of the support structure can utilize the one or more tubes without the body 412 or a smaller body (e.g., a body that merely cooperates one or more tubes together).

In some embodiments, the one or more wire apertures 414 of the support structure 410 positions the wire apertures to guides and/or position the wires, and in some instances, maintain some separation between the wires at least at the top of the potting material. This separation between wires allows the potting material between the wires to permit the potting material to more readily bond with the wire and in some instances completely surround and bond with the jacket of the wire 116 and/or the sleeve 614 secured with the jacket. The above embodiments are generally described such that the support structure is cooperated with the device 110 prior to the potting material curing within the housing. In some instances, the support structure is cooperated with the housing after the potting material is added into the volume 312. In some embodiments, the support structure 410 is cooperated with the device 110 after the potting material is cured. For example, the support structure can be secured with an exterior of the housing 112 with the wires 116 extending from the cured potting material to be inserted and/or threaded through and extend out of the wire apertures 414.

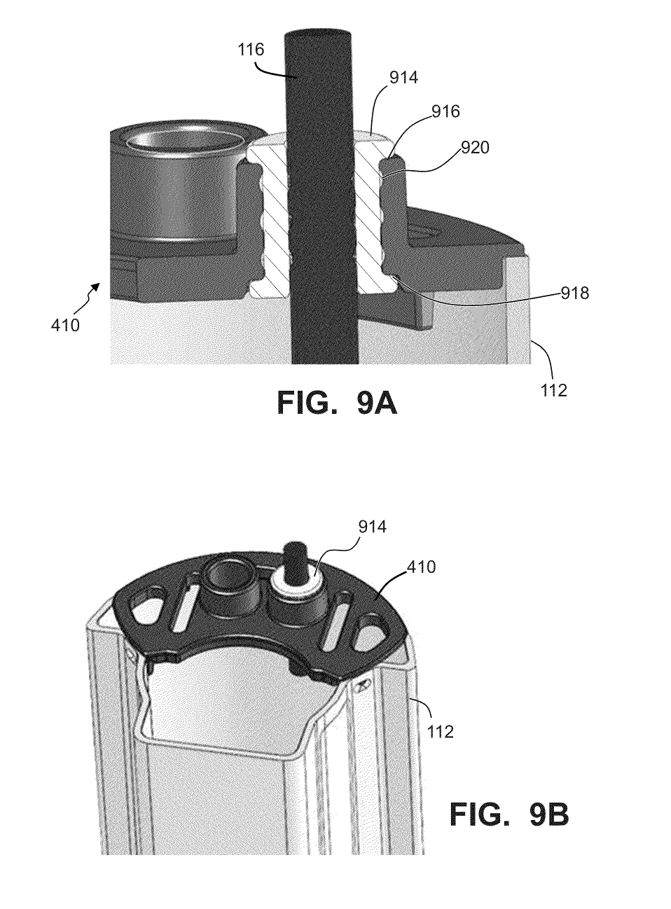

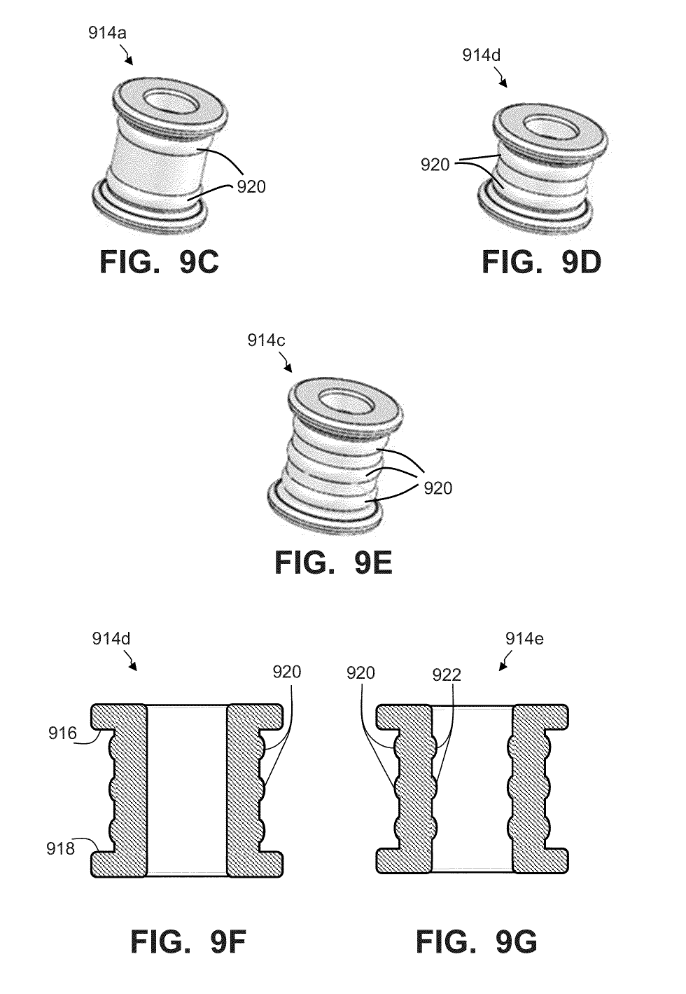

FIG. 9A shows a partial cross-sectional view of the support structure 410 with an exemplary sleeve 914 that cooperates with and/or is fixed to the jacket of a wires 116, in accordance with some embodiments. FIG. 9B shows the support structure 410 of FIG. 9A with the exemplary sleeve 914 positioned within a wire aperture 414 of the support structure 410, in accordance with some embodiments. FIGS. 9C-9E show representations of exemplary sleeves 914a-914c, respectively, in accordance with some embodiments. Further, FIGS. 9F-9G show cross-sectional views of exemplary sleeves 914d and 914e, respectively, in accordance with some embodiments. Referring to FIGS. 9A-9G, the sleeves 914 are configured to cooperate with the wire 116 and secured with the wire aperture 414 of the support structure. In some embodiments, the sleeve 914 includes a lip or ledge 916, 918 at the top and/or the bottom that at least aids in maintaining a position of the sleeve and wire 116. Further, in some embodiments, the sleeve includes one or more ridges 920, spines, furrow, bumps, grooves, channels, or the like formed on an exterior surface of the sleeve. For example, the sleeve can be configured with one or more annular ridges 920 extending around at least a portion of an exterior circumference. Similarly, some embodiments include one or more ridges 922, spines, furrow, bumps, grooves, channels, or the like formed on an interior surface of the sleeve, and/or extending around an inner circumference of the sleeve.

The sleeve 914 is configured to be positioned at least partially within the wire aperture, and in many embodiments, extend through the wire aperture. The one or more ledges 916, 918 and/or opposing ends of the sleeve can be configured to cooperate with the wire aperture to maintain a position of the sleeve and wire, and in some instances establish a seal with the wire aperture. For example, the ledges in some implementations have a width or diameter that is greater than the width or diameter of the wire aperture and extends over and can be configured to contact surfaces of the support structure surrounding the wire aperture. In some embodiments, some or all of the sleeve 914 can be configured from an elastic material allowing it to at least partially compress within the wire aperture and/or to be compressed while a portion is inserted through the wire aperture such that one or both the ledges 916, 918 extend out of the wire aperture. Further, in some embodiments, the wall of the wire aperture 414 includes one or more grooves, channels, ridges, spines, furrow, bumps or the like formed on the surface of the wire aperture and configured to cooperate with and/or mate with one or more corresponding ridges 920, spines, furrow, bumps, grooves, channels of the sleeve 914.

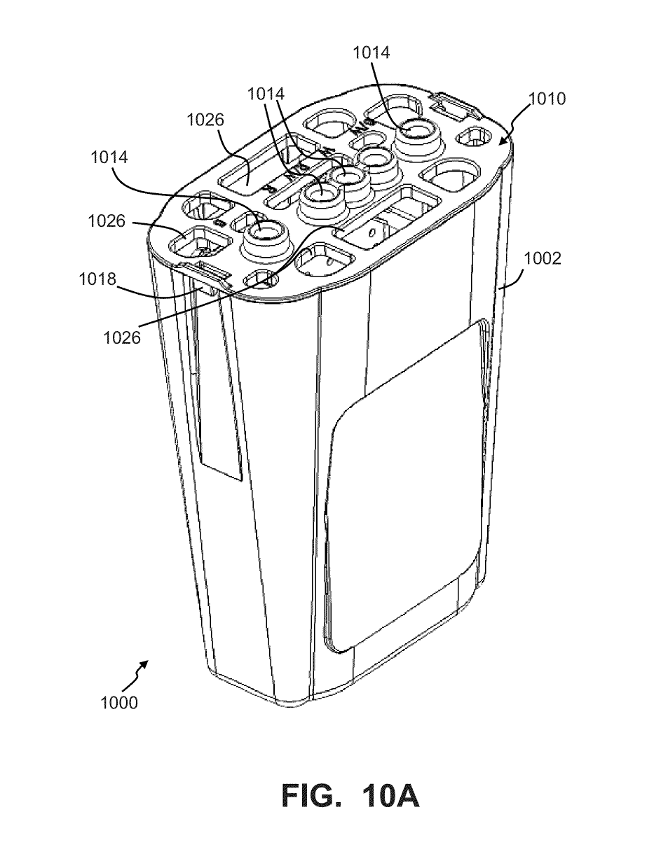

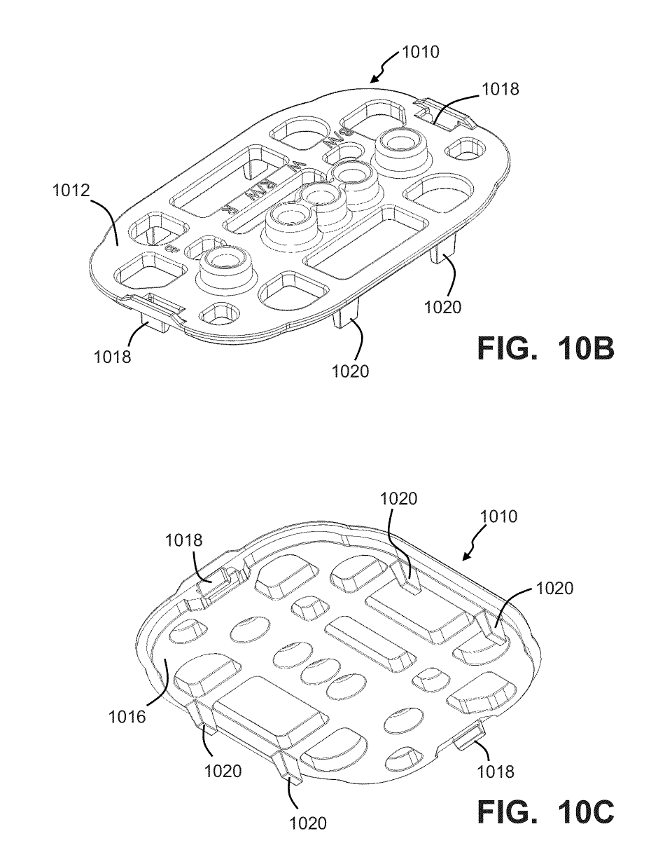

FIG. 10A depicts a perspective view of an exemplary device 1000 comprising a housing 1002 and a support structure 1010 cooperated with the housing, in accordance with some embodiments. FIG. 10B depicts a perspective view of the exemplary support structure 1010 of FIG. 10A showing an exterior or top surface 1012 of the support structure, where the exterior surface 1012 is exposed and exterior to the housing 1002 when the support structure is cooperated with and/or secured with the housing 1002, in accordance with some embodiments. FIG. 10C depicts a perspective view of the exemplary support structure 1010 of FIG. 10A showing an interior or bottom surface 1016 of the support structure, where the interior surface 1016 faces interior to the housing 1002 when the support structure is cooperated with and/or secured with the housing 1002, in accordance with some embodiments.

Referring to FIGS. 10A-10C, similar to the support structure 410 of FIGS. 4A-4B, the support structure 1010 includes one or more wire apertures 1014. Wires 116 are not depicted in FIG. 10A for simplicity; however, those skilled in the art will appreciate that wires may pass through one or more of the wire apertures 1014. The support structure 1010 may include multiple wire apertures 1014, and in some instances the wire apertures may vary in size, for example, depending on expected wire size and/or the number of wires to pass through a wire aperture. One or more additional holes or apertures 1026 may be included in the support structure 1010, which can in part allow gas to escape from under the support surface as one or more potting materials are added to a volume within the housing 1002.

In some embodiments, the support structure 1010 is secured with the housing 1002 through a clip, latch, hemispherical snap feature, or other such feature. For example, the support structure 1010 can include one or more biased latches 1018 that cooperate with a corresponding ledge, lip, slot, hole or other such structure of the housing 1002. Further, in some embodiments, the support structure includes one or more positioning protrusions 1020, extensions, fins, blades, guides or the like that can cooperate with the housing 1002 to aid in proper positioning and/or alignment of the support structure.

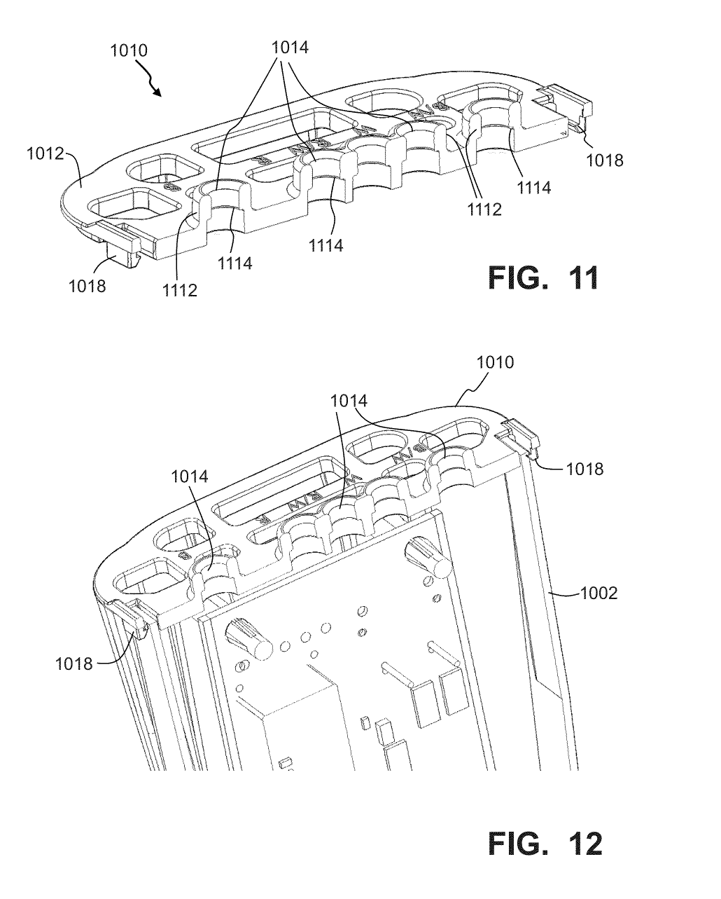

FIG. 11 shows a cross-sectional, perspective view of the support structure 1010 of FIG. 10A, in accordance with some embodiments. FIG. 12 shows a cross-sectional, perspective view of the support structure 1010 cooperated with the housing 1002, in accordance with some embodiments. Referring to FIGS. 10A-12, the support structure includes one or more wire apertures 1014 through which the wires extend. In some embodiments, the support structure 1010 includes tubes 1112, channels or other such structures cooperated with one or more of the wire apertures 1014. Each tube 1112 extends the corresponding wire aperture 1014 above the exterior surface 1012, similar to the configurations described above. Further, in some embodiments, one or more of the tubes 1112 may include a lip or ledge 1114 that is configured to cooperate with a sleeve 614 secured with the wire to position the wire, transfer forces to the support structure 1010 and/or inhibit movement of the wire at least proximate an interface between the wire and the potting material.

As described above, the support structures include wire apertures. The wire apertures can be configured to receive one or more wires. Some embodiments are configured to provide support structures with wire apertures to receive multiple wires. In some of these configurations, one or more separators may be included in the wire aperture to provide some separation of the wires.

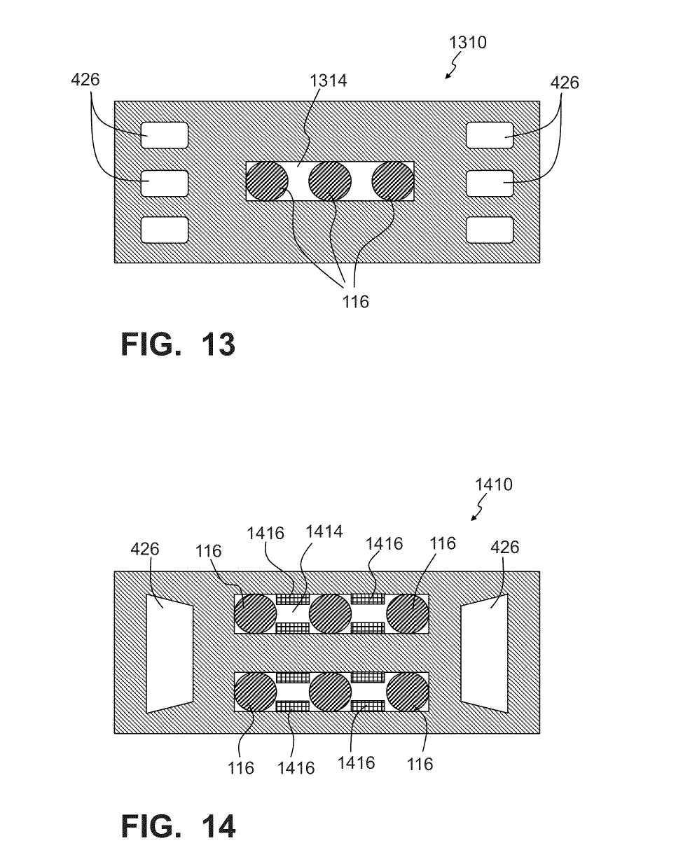

FIG. 13 shows a simplified, plan view of an exemplary support structure 1310, in accordance with some embodiments. The support structure 1310 comprises a wire aperture 1314 configured to receive multiple electrical conduits, cables and/or wires 116.

In some embodiments, the support structure 1310 includes one or more additional apertures 426.

FIG. 14 shows a simplified, plan view of an exemplary support structure 1410, in accordance with some embodiments. The support structure 1410 comprises one or more wire apertures 1414 configured to receive multiple wires 116. In some embodiments, the wire aperture 1414 includes spacers 1416 that space the wires 116 from neighboring wires. Again, in some instances, one or more additional apertures 426 may be incorporated in the support structure 1410.

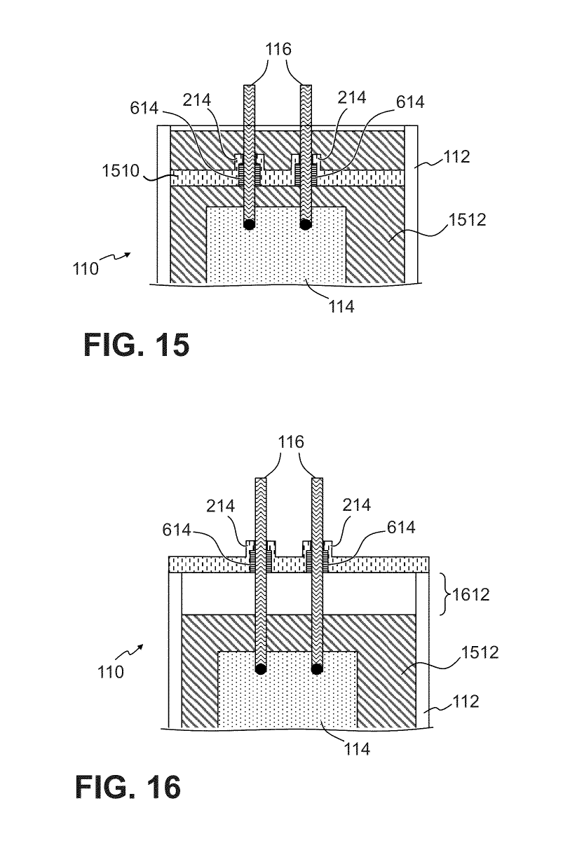

FIG. 15 shows a simplified, partial, cross-sectional view of a support structure 1510 fixed with a housing 112 of a device 110, in accordance with some embodiments.

In this configuration, the support structure 1510 is positioned within the volume of the housing 112. The wires 116 extend from the circuit board 114 and through the wire apertures 214. Typically, one or more sleeves 614 are secured with each of the wires 116 and physically contact and/or interface with respective wire apertures 214. In some embodiments, with the support structure 1510 positioned within the housing 112, the potting material 1512 encapsulates the support structure 1510. Even with the support structure 1510 encapsulated by the potting material and/or the potting material extending above the support structure, the support structure continues to relieve strain on at least those portion of the wires between the support structure 1510 and the circuit board 114 and/or the contacts with the circuit board due to external forces applied on the wires.

FIG. 16 shows a simplified, partial, cross-sectional view of a support structure 1610 fixed with a housing 112 of a device 110, in accordance with some embodiments. In this configuration, the support structure 1610 is fixed with the housing 112, with the potting material 1512 not in contact with the support structure 1610 and separated from the support structure by a distance 1612. The wires 116 extend from the circuit board 114, which is encapsulated by the potting material 1512, and through the wire apertures 214. Again, one or more sleeves 614 may be secured with one or more of the wires 116 and physically contacting and/or interfacing with respective wire apertures 214. The support structure 1610 continues to relieve strain on one or more wires 116 extending into the potting material 1512 and/or the connection of the wire with the circuit board 114 due to external forces applied on the wires even with the separation 1612 between the potting material 1512 and the support structure 1610.

In some embodiments the support structure may include one or more wire clamps. The wire clamp is configured to receive one or more wires 116 and to mechanically clamp, squeeze or secure the one or more wires. The wire clamp can be a screw clamp, may include one more biasing member and/or other such configurations. Some embodiments comprise a screw clamp that utilize one or more screws or other such devices that allow the clamp to be tightened against and/or around the one or more wires. In some instances, the screw clamp is part of one or more wire apertures and/or cooperates with one or more apertures. With at least some screw clamps, the one or more wires are positioned through and/or adjacent a screw clamp and the screw clamp is tightened to affix the wires. For example, one or more clamps can be similar to or the same as screw clamps used with Romex wires or cables, with the clamp being secured with the support structure, housing and/or potting material.

The one or more clamps (e.g., screw clamp) can inhibit axial and/or longitudinal forces from disturbing the wire/potting interface. Some embodiments include one or more clamps that comprise one or more biased members that are biased to press against the one or more wires when the wires in passed through the wire clamp and/or the wire apertures 414. The biasing can be achieved through one or more springs, the construction of the biasing member and/or other such biasing. Other such mechanisms can be used to position and/or secure the wires 116 relative to the support structure 410, potting material and/or housing 112. Some embodiments may additionally utilize an adhesive or other such bonding between the wire clamp and the one or more wires 116 clamped by the wire clamp. In some instances, the wire clamp is secured with or coupled with the support structure and can work cooperatively with the support structure. In some implementations, the positioning of the wire clamp may restrict movement of the wire clamp (e.g., through contact with the support structure and/or housing 112).

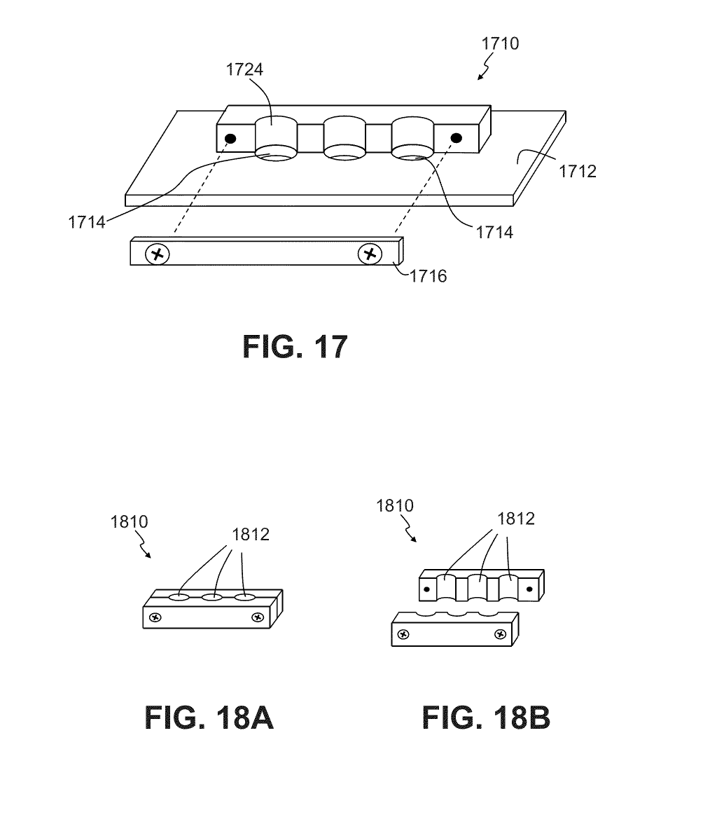

For example, FIG. 17 shows a simplified perspective view of an exemplary support structure 1710 in accordance with some embodiments. The support structure 1710 includes a body 1712, one or more wire apertures 1714 and one or more wire clamps 1716. The wire apertures 1714 are formed within the body 1712 and are configured to allow one or more wires to extend through each the one or more wire apertures with the support structure positioned relative to a housing and/or potting material. The one or more wire clamps 1716 are formed as part of the body 1712, secured with the body or otherwise positioned proximate the body 1712.

In some embodiments, the wire clamp 1716 is formed of two parts that are secured together, for example with one or more screws, bolts, pins, friction fittings, snap fittings, adhesive, bonding and/or other such mechanisms. The two parts can be cooperated and positioned about the one or more wires to clamp the one or more wires, cables and/or other such electrical conduit into position within and extending through channels 1724 of the wire clamp 1716. One or more wires can extend through each wire aperture 1714 and/or one or more wires can extend through each channel 1724 of the wire clamp 1716. Still further, in some embodiments, multiple wires can be secured within a single jacket, such as a multi-conductor cable, and one or more multi-conductor cables and/or wires can extend through the wire aperture 1714 and channel 1724 to be secured at least in part with the wire clamp.

Further, the embodiment depicted in FIG. 17 show a single wire clamp 1716 with multiple channels 1724. In other embodiments, a wire clamp can be configured to cooperate with a single wire aperture 1714. For example, some embodiments utilize multiple different wire clamps. Additionally, the wire clamp 1716 depicted in FIG. 17 is merely one example of many types of wire clamps that may be employed. Still further, in other embodiments, the wire clamp 1716 may be utilized in addition to tubes 416 of the support structure (e.g., coupled with, and/or positioned adjacent the tubes) or as part of or in place of the tubes.

As described above, in some embodiments the one or more sleeves 614 can receive and secure with one or more wires and/or conductor cable. Further, a sleeve can include one or more pieces that cooperate to secure with the wire. FIGS. 18A-18B depict simplified perspective views of an exemplary sleeve 1810 in accordance with some embodiments. The sleeve 1810 is formed from one or more parts that are cooperated to define one or more wire channels 1812. In some embodiments, the two parts can be secured together through substantially any relevant method, such as but not limited to one or more screws, bolts, pins, friction fittings, snap fittings, adhesive, bonding and/or other such methods. Again, one or more wires or cables are configured to extend through and be secured with the one or more wire channels 1812. In some implementations, a conductor cable with multiple wires within a single jacket or other such insulation can extend through and be secured with a wire channel 1812 of the sleeve 1810. The sleeve 1810 cooperates with the support structure, housing and/or potting material to redistributes forces and inhibit movement of the wires at least at the interface of the wire with the potting material and/or inhibits deformation of the potting material at the interface. FIGS. 18A-18B show an exemplary sleeve configured to cooperate with more than one wire. Other embodiments, however, comprise multiple pieces and are configured to cooperate with a single wire or multiple wires. Similarly, a single wire aperture can be configured to receive multiple wires.

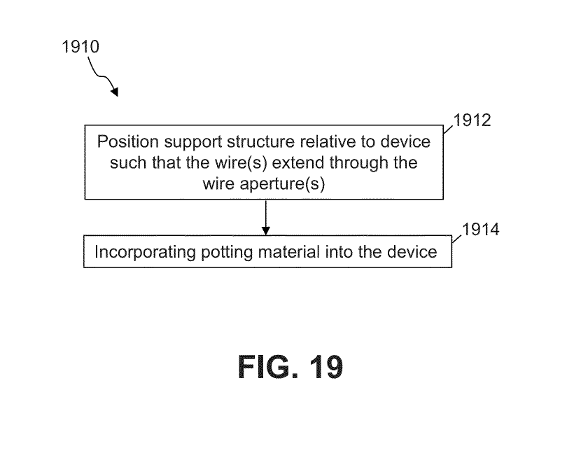

FIG. 19 shows a simplified flow diagram of an exemplary process 1910 of protecting electrical components of a device, in accordance with some embodiments. In step 1912, a support structure 410 is positioned relative to a device 150 such that the one or more wires 116 extend through the one or more wire apertures 414. As described above, the device comprises one or more electrical components (e.g., circuit board 154) within a volume 312 defined by a housing 152 of the device. One or more of the wires 156 couple with the one or more electrical components and extend out of the housing of the device. In positioning the support structure, the one or more wires coupled with the electrical components are inserted through one or more wire apertures 414 formed in the support structure 410.

In step 1914, a potting material 810 is incorporated into the volume to encapsulate at least part of the electrical components and at least a portion of the one or more wires 156 within the volume 312. The support structure is configured to contact the one or more wires and is configured to inhibit movement of the wires relative to the potting material due to external forces applied to the wires to reduce the forces applied to the potting material. In some embodiments, the one or more wire apertures 414 are configured to contact and/or support the corresponding one or more wires to inhibit movement of the wires at least proximate the interface between the potting material and a jacket of the wire. The incorporation of the potting material, in some embodiments, comprises incorporating the potting material 810 to contact the support structure 410. The potting material can be cured while in contact with the support structure such that the potting material bonds with the support structure as the potting material cures.

In some embodiments, one or more processes further include securing at least one sleeve 614 with an exterior of each of the one or more wires 156. The one or more wires are inserted through the one or more wire apertures 414 such that each of the sleeves 614 secured with the one or more wires 156 is in contact with the support structure 410 and inhibits further movement of the one or more wires from extending in an axial direction further out of a corresponding one of the one or more wire apertures. Further, in at least some implementations, each of the sleeves transfers at least external axial forces applied to the one or more wires to the support structure and further inhibits movement of the wires at least proximate the interface between the potting material and the jacket of the wire. Further, the at least one sleeve 614 can be secured with the exterior of each of the one or more wires and positioned along a length of each of the one or more wires such that when in contact with the support structure and when the support structure 410 is positioned relative to the device and pre-load force is applied by each of the at least one sleeves onto the support structure. In some embodiments, the positioning of the support structure 410 relative to the device 150 includes securing the support structure with the housing 152 of the device such that a position of the support structure relative to the housing is maintained.

What is claimed is:

1. An apparatus providing an electrical conductor guide for use with an irrigation device comprising:
a housing having a volume and containing an electronic component and one or more electrical conductors coupled thereto;
a support structure having one or more apertures each configured to allow at least one of the one or more electrical conductors to extend therethrough; and
a potting material at least partially filling the volume and sealing the volume from an external environment, wherein the one or more electrical conductors extend out of the potting material and the housing;
wherein the support structure is cooperated with the one or more electrical conductors and is configured to inhibit movement of the one or more electrical conductors relative to the potting material due to external forces applied to the one or more electrical conductors to reduce the forces applied to the potting material or to the electronic component.

2. The apparatus of claim 1, wherein the support structure is further configured to reduce deformation of the potting material at the interface between the one or more electrical conductors and the potting material.

3. The apparatus of claim 1, wherein the support structure is in contact with the housing, and wherein the support structure is configured to transfer the forces on at least one of the one or more electrical conductors to the housing.

4. The apparatus of claim 1, wherein the support structure further comprises one or more tubes extending from a surface of the support structure, wherein the one or more tubes comprise the one or more apertures.

5. The apparatus of claim 1, further comprising:
one or more sleeves, wherein each of the one or more electrical conductors has at least a corresponding one of the one or more sleeves secured with at least one of the one or more electrical conductor, and wherein the one or more sleeves have a width when secured with the electrical conductor that is greater than a width of the at least one of the one or more electrical conductors and is configured to contact the support structure.

6. The apparatus of claim 5, wherein the width of the sleeve is greater than a width of a corresponding one of the one or more apertures.

7. The apparatus of claim 1, wherein the support structure is plate configuration.

8. The apparatus of claim 1, wherein the support structure is positioned relative to the potting material such that at least a portion of the support structure is in contact with at least some of the potting material.

9. The apparatus of claim 1, further comprising
a cable comprising two or more of the one or more electrical conductors, wherein the two or more electrical conductors electrically couple with one or more electrical components within the housing;
wherein the support structure is positioned such that the cable extends through one of the one or more apertures with the support structure in contact with the cable inhibiting movement of the cable relative to an interface between the potting material and the cable.

10. A method of protecting electrical components of an irrigation device, the method comprising:
positioning a support structure relative to a device, the support structure comprising one or more apertures formed in the support structure and the device comprising one or more electrical components within a volume defined by a housing of the device with one or more electrical conductors coupled with the one or more electrical components and extending out of the housing, wherein the positioning the support structure comprises positioning the support structure such that the one or more electrical conductors extend through the one or more apertures and out of the housing of the device; and
incorporating a potting material into the volume to encapsulate at least part of the electrical components and at least a portion of the one or more electrical conductors within the volume;
wherein the one or more apertures are configured to support the corresponding one or more electrical conductors to inhibit movement of the one or more electrical conductors at least proximate an interface between the potting material and the one or more electrical conductor.

11. The method of claim 10, wherein the incorporating the potting material comprises incorporating the potting material to contact the support structure; and
curing the potting material while in contact with the support structure such that the potting material bonds with the support structure as the potting material cures.

12. The method of claim 10, further comprising:
securing at least one sleeve with an exterior of each of the one or more electrical conductors; and
inserting the one or more electrical conductors through the one or more apertures such that each of the sleeves secured with the one or more electrical conductors is in contact with the support structure and inhibits further movement of the one or more electrical conductors from extending in an axial direction further out of a corresponding one of the one or more apertures, and such that each of the sleeves transfers at least external axial forces applied to at least one of the one or more electrical conductors to the support structure and further inhibits movement of the one or more electrical conductors at least proximate the interface between the potting material and the one or more electrical conductors.

13. The method of claim 12, wherein the securing the at least one sleeve with the exterior of each of the one or more electrical conductors comprises securing the at least one sleeve at a position along a length of each of the one or more electrical conductors such that when in contact with the support structure and when the support structure is positioned relative to the device a pre-load force is applied by each of the at least one sleeves onto the support structure.

14. The method of claim 10, wherein the positioning the support structure relative to the device comprises securing the support structure with the housing of the device such that a position of the support structure relative to the housing is maintained.
